(19) United States
(12) Patent Application Publication
(10) Pub. No.: US 2014/0196942 A1
(43) Pub. Date: Jul. 17, 2014

(54) ELECTROMAGNETIC WAVE SHIELDING MEMBER

(71) Applicant: Panasonic Corporation, Osaka (JP)

(72) Inventors: Atsushi SUWA, Osaka (JP); Masakazu ADACHI, Osaka (JP)

(73) Assignee: Panasonic Corporation, Osaka (JP)

(21) Appl. No.: 14/153,337

(22) Filed: Jan. 13, 2014

(30) Foreign Application Priority Data
Jan. 16, 2013 (JP) 2013-005421

(51) Int. Cl. H05K 9/00

(52) U.S. Cl. CPC H05K 9/00
USPC 174/350

(57) ABSTRACT

An electromagnetic wave shielding member includes a dielectric layer, first conductor plates arranged on one surface of the dielectric layer, and second conductor plates arranged opposed to the first conductor plates on the other surface of the dielectric layer, wherein the first and second conductor plates are arranged at regular intervals to have three or more-fold rotational symmetry about an optional reference point on the one surface of the dielectric layer on which the first conductor plates are arranged, and are arranged independent from each other.

### BACKGROUND OF THE INVENTION

The present invention relates to an electromagnetic wave shielding member which shields an electromagnetic wave.

A microwave heating technique has features such as interior heating, high-speed heating, selective heating, and high efficiency has been applied to the industrial field. Generally, metal is used for a furnace wall of a microwave heating furnace to prevent a leak of an electromagnetic wave. As a result, change in a state of a material to be heated cannot be visually checked. On the other hand, a microwave oven, which uses the same microwave heating applied technique, has a window on a door so that a user can check a state of a material to be cooked from outside. FIG. 10 shows an electromagnetic wave shielding member of a conventional art. The window has a structure in which a punching metal 501 having a large number of small holes 401 in a thin plate-shaped metal 301 is covered with a glass plate (not shown). A leak of an electromagnetic wave can thus be prevented. In addition, a state of a material to be cooked can be visually checked through the small holes.

An energy transmissivity of an electromagnetic wave from each of the small holes 401 in the punching metal 501 is expressed by Equation (1).

r≈23×(a/λ)⁴ (1)

where r: transmissivity, a: a diameter of the small hole 401, and λ: a wavelength of the electromagnetic wave (a<<λ).

For example, when the diameter of the small hole 401 is 30 mm with respect to the wavelength of approximately 120 mm of the electromagnetic wave (2.45 GHz) in a vacuum used for a microwave oven, transmissivity r of the electromagnetic wave is r=0.089. As a result, approximately 91% of the electromagnetic wave is shielded, and approximately 9% of the electromagnetic wave is transmitted.

The transmitted electromagnetic wave in a microwave oven is standardized to be 1 mW/cm² or less. When a size of a window of a microwave oven is 30 cm×15 cm=approximately 450 cm², electric power of an allowed leaked electromagnetic wave is 1 mW/cm²×450 cm²=450 mW or less. When an output of a microwave oven for industrial use is 1800 W, the transmissivity is 0.45 W/1800 W×100=0.025%. A shielding rate of 99.975% or more is thus necessary. To satisfy this shielding rate, the diameter of the small hole 401 calculated from Equation (1) is required to be 6.8 mm or less.

Since the diameter of the small hole 401 is sufficiently larger than a wavelength of visible light (approximately, 360 to 830 nm) the visible light is not shielded. This can ensure visibility of a material to be heated to prevent a leak of an electromagnetic wave (for example, see Patent Literature 1 (JP 5-146830 A)).

Actually, to ensure good visibility, a large number of small holes 401 having a smaller diameter such as 1 mm are used.

However, the above-described structure has the following disadvantages. For example, the diameter of the small hole 401 in the punching metal 501 is 1 mm, and punching is then performed so that centers of three holes are connected to form a regular triangular shape. To ensure strength, an aperture ratio is approximately 50%. At the aperture ratio of approximately 50%, an interior of a microwave oven can only be checked unclearly, and the aperture ratio is not sufficient for observing details of a material to be heated. To increase the aperture ratio, the diameter of the hole can be made smaller to increase the number of holes. However, only a several-percent effect can be obtained.

### SUMMARY OF THE INVENTION

The present invention has been made in view of the reasons above, and an object of the present invention is to provide an electromagnetic wave shielding member which can ensure a sufficiently high aperture ratio.

In order to accomplish the above object, according to one aspect of the present invention, there is provided an electromagnetic wave shielding member comprising:

a first dielectric layer;

a plurality of first conductor members arranged on one surface of the first dielectric layer; and

a plurality of second conductor members arranged opposed to the first conductor members on an other surface of the first dielectric layer,

wherein the first and second conductor members are arranged at regular intervals to have three or more-fold rotational symmetry about an optional reference point on the one surface of the first dielectric layer on which the first conductor members are arranged, and are arranged independent from each other to form a gap between adjacent conductor members.

In the electromagnetic wave shielding member according to the present invention, each of the first conductor members and each of the second conductor members may have a same shape and a same size, and are arranged in a same position on the one surface and the other surface of the first dielectric layer.

In the electromagnetic wave shielding member according to the present invention, the first dielectric layer may be constructed by a space surrounded by second dielectric layers and sealing members and filled with gas or maintaining a vacuum therein.

According to the aspects of the present invention, the electromagnetic wave shielding member has an aperture larger than that in the conventional art. An aperture ratio higher than that in the conventional art can be ensured to greatly improve visibility of a material to be heated. In addition, according to the aspect of the present invention, the first dielectric layer includes the space surrounded by the second dielectric layers and the sealing members and filled with the gas or the space which maintains the vacuum therein. Thus, not only a leak of an electromagnetic wave but also heat conduction can be reduced. Further, according to the aspect of the present invention, since a frequency of an attenuation pole is determined according to a size of each of the first conductor plates and each of the second conductor plates, the electronic wave shielding member according to the aspect of the present invention is applicable to a microwave, a millimeter wave, or an infrared ray.

### BRIEF DESCRIPTION OF THE DRAWINGS

Before the description of the present invention proceeds, it is to be noted that like parts are designated by like reference numerals throughout the accompanying drawings:

FIG. 1 is a cross-sectional view of an electromagnetic wave shielding member according to a first embodiment of the present invention;

FIG. 2 is a top view of the electromagnetic wave shielding member according to the first embodiment of the present invention;

FIG. 3 is a graph showing pass-through characteristics of the electromagnetic wave shielding member according to the first embodiment of the present invention;

FIG. 4 is a top view of an electromagnetic wave shielding member of a comparative example with respect to the first embodiment of the present invention;

FIG. 5 is a graph showing pass-through characteristics of the electromagnetic wave shielding member according to the first embodiment of the present invention;

FIG. 6 is a view showing polarized wave dependency of the electromagnetic wave shielding member according to the first embodiment of the present invention;

FIG. 7 is a view for describing the polarized wave dependency according to the first embodiment of the present invention;

FIG. 8 is a view for describing a size according to the first embodiment of the present invention;

FIG. 9 is a cross-sectional view of an electromagnetic wave shielding member according to a modification example of the first embodiment of the present invention; and

FIG. 10 is a view showing an electromagnetic wave shielding member of a conventional art described in Patent Literature 1.

### DETAILED DESCRIPTION OF THE EMBODIMENTS

Hereinafter, an embodiment of the present invention will be described with reference to the drawings.

### First Embodiment

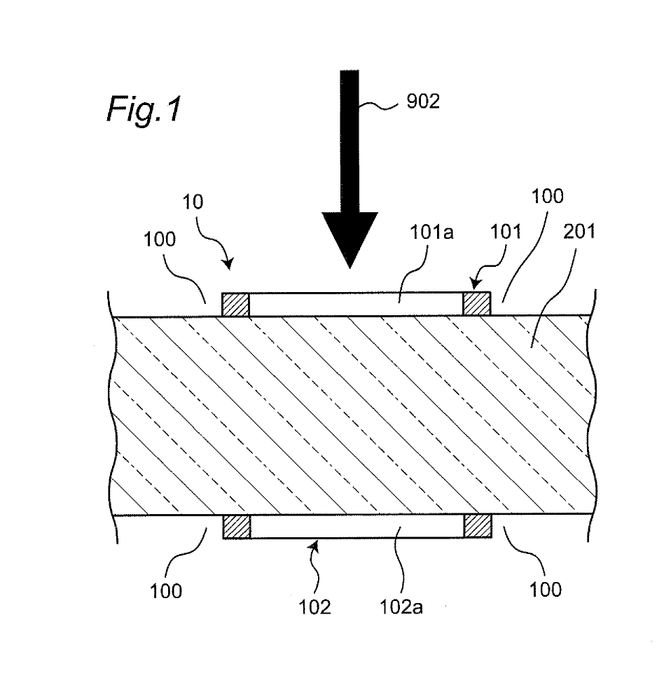

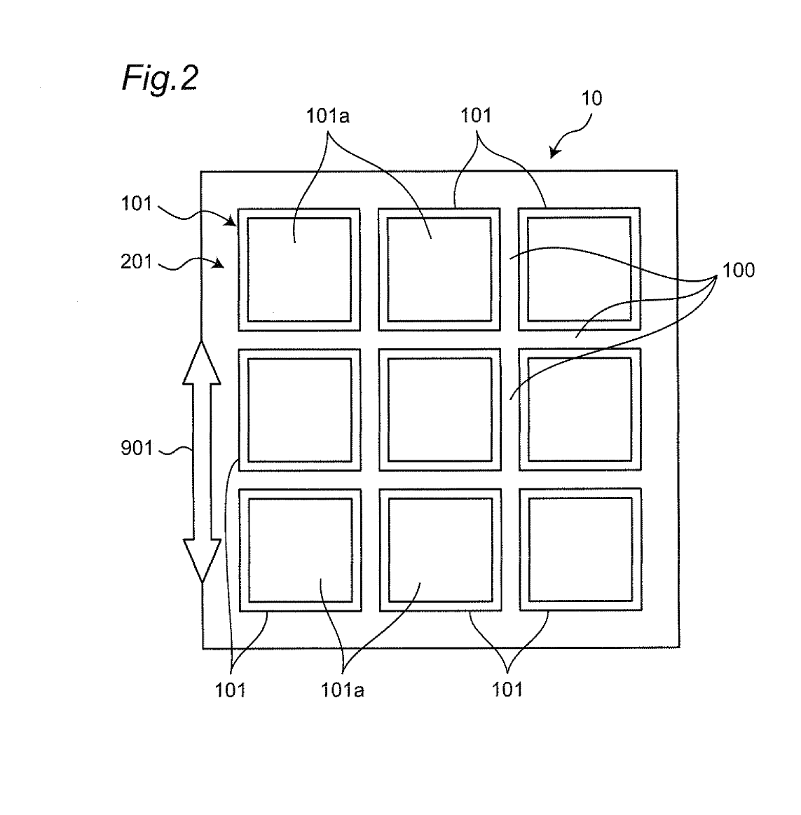

FIG. 1 shows a partially cross-sectional view of an electromagnetic wave shielding member 10 of a first embodiment. FIG. 2 shows a top view of the electromagnetic wave shielding member 10 of the first embodiment. As one example, the electromagnetic wave shielding member 10 is used for a door of a microwave oven, but the present invention is not limited thereto.

In the electromagnetic wave shielding member 10, a first conductor plate 101 and a second conductor plate 102 having the same quadrilateral frame shape are arranged opposed to each other on both surfaces of a dielectric layer 201 which are planes parallel to each other. Further, a plurality of first conductor plates 101 and a plurality of second conductor plates 102 are arranged at regular intervals in the planes of the dielectric layer 201, and are arranged independent from each other (with a gap 100 between adjacent conductor plates). In other words, a large number of first conductor plates 101 and a large number of second conductor plates 102 are fixed onto the respective surfaces of the dielectric layer 201 to have a predetermined pattern at predetermined intervals. Here, each of the first conductor plates 101 is an example of a first conductor member, and each of the second conductor plates 102 is an example of a second conductor member. Each of the conductor members can thus be formed by a conductor plate in plate shape (or a conductor plate in frame shape). When visibility is required, the dielectric layer 201 is transparent or has translucency. As an example of the structure in which the conductor plates are arranged at regular intervals, and are arranged independent from each other, all the first conductor plates 101 have the same shape (by way of example, the square frame shape) and the same size, and are fixed onto one surface of the dielectric layer 201 at equal intervals in a 3×3 matrix. A plurality of gaps 100 are provided at predetermined intervals (e.g., at equal intervals). Each of the gaps 100 is formed between adjacent first conductor plates 101. Each of the second conductor plates 102 has the same shape and size as each of the first conductor plates 101, and is fixed in the same position as the first conductor plate 101 in the same manner. A plurality of gaps 100 are provided at predetermined intervals (e.g., at equal intervals). Each of the gaps 100 is formed between a plurality of adjacent second conductor plates 102. A square hole 101a extends through each of the first conductor plates 101, and a square hole 102a extends through each of the second conductor plates 102. An interior of a member covered with the electromagnetic wave shielding member 10 (e.g., a state of an interior of the microwave oven) can thus be seen through the through-holes 101a and 102a and the transparent dielectric layer 201.

An electromagnetic wave is incident onto the electromagnetic wave shielding member 10 in an incident direction 902 of the electromagnetic wave in FIG. 1. A direction of a polarized wave is a direction 901 in FIG. 2. Each of the first conductor plates 101 is electromagnetically coupled to the adjacent first conductor plate 101 and the opposing second conductor plate 102 by electric currents excited by the incident electromagnetic wave. The electromagnetic wave shielding member 10 which shields the electromagnetic wave having a particular frequency is thus formed.

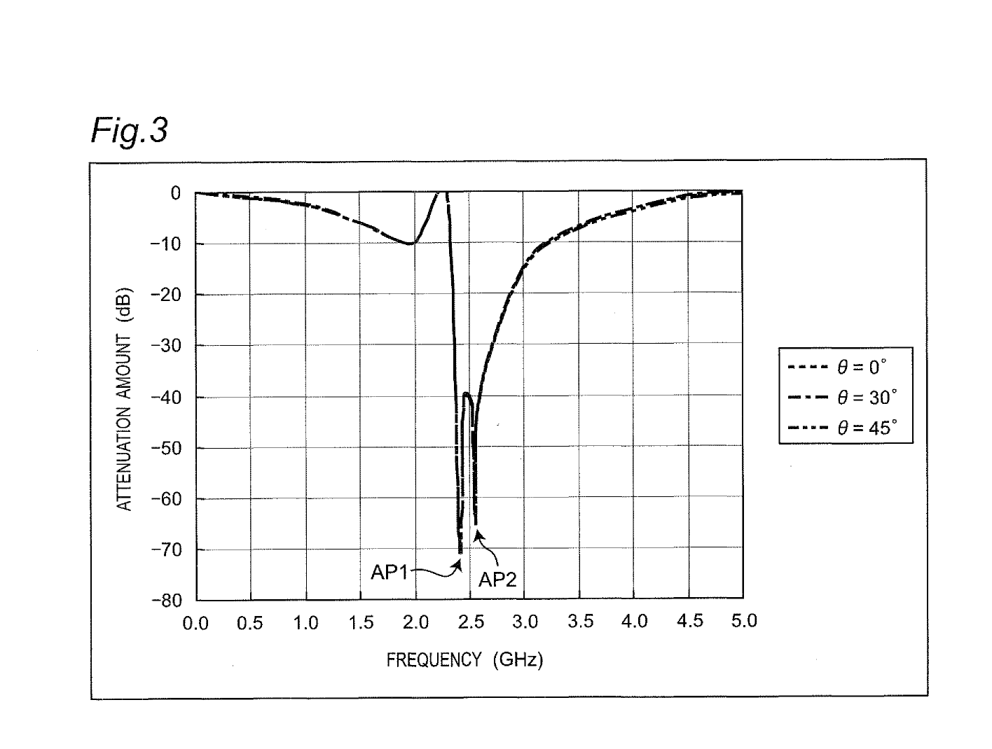

For example, FIG. 3 shows electromagnetic wave pass-through characteristics in the case where the dielectric layer 201 is a glass having a thickness of 2.5 mm and a relative permittivity of 7 and each of the first conductor plates 101 and each of the second conductor plates 102 have a line width of 0.1 mm and the square frame shape with an outer shape of 15 mm. In FIG. 3, it is found that around 2.5 GHz, an attenuation amount of 36 dB or more (a transmission amount of 1/4000 or less) is ensured at a bandwidth of approximately 300 MHz. The attenuation amount of 36 dB is equivalent to the electromagnetic wave shielding rate of 99.975%. It is found that this satisfies the shielding rate required for the electromagnetic wave shielding member of a window of the microwave oven.

In the pass-through characteristics, a point at which a decrease is changed to an increase is referred to as an “attenuation pole”. In the pass-through characteristics in FIG. 3, there are two attenuation poles, i.e., an attenuation pole AP1 near 2.4 GHz and an attenuation pole AP2 near 2.55 GHz. The attenuation poles AP1 and AP2 are generated as follows. The electromagnetic wave is incident onto each of the first conductor plates 101 and each of the second conductor plates 102. Then, the electric current flows into the first conductor plate 101 and the second conductor plate 102. The first conductor plate 101 is electromagnetically coupled to the adjacent first conductor plate 101 and the opposing second conductor plate 102 across the dielectric layer 201.

In this manner, the first conductor plate 101 and the adjacent first conductor plate 101 are adjacently arranged at regular intervals on the dielectric layer 201. In addition, the first conductor plate 101 and the opposing second conductor plate 102 are arranged across the dielectric layer 201. The two attenuation poles are thus generated to realize a wide bandwidth.

In addition, an aperture ratio of the electromagnetic wave shielding member 10 of this structure is 95% or more to realize good visibility.

Further, in FIG. 2, θ is defined as an angle with respect to the direction 901. In FIG. 2, it is found that even if the angle θ is changed to 0°, 30°, and 45°, the pass-through characteristics coincide with each other. Accordingly, the electromagnetic wave shielding member 10 having the structure shown in FIGS. 1 and 2 can respond regardless of the direction of the polarized wave of the electromagnetic wave, and shield the electromagnetic wave.

By way of example, each of the conductor plates 101 and 102 of the electromagnetic wave shielding member 10 of this structure has the square-frame-shaped outer shape of 15 mm which is larger than the diameter of 6.8 mm or less of the punching metal of the conventional art. Thus, the conductor plates 101 and 102 of the electromagnetic wave shielding member 10 can be easily manufactured.

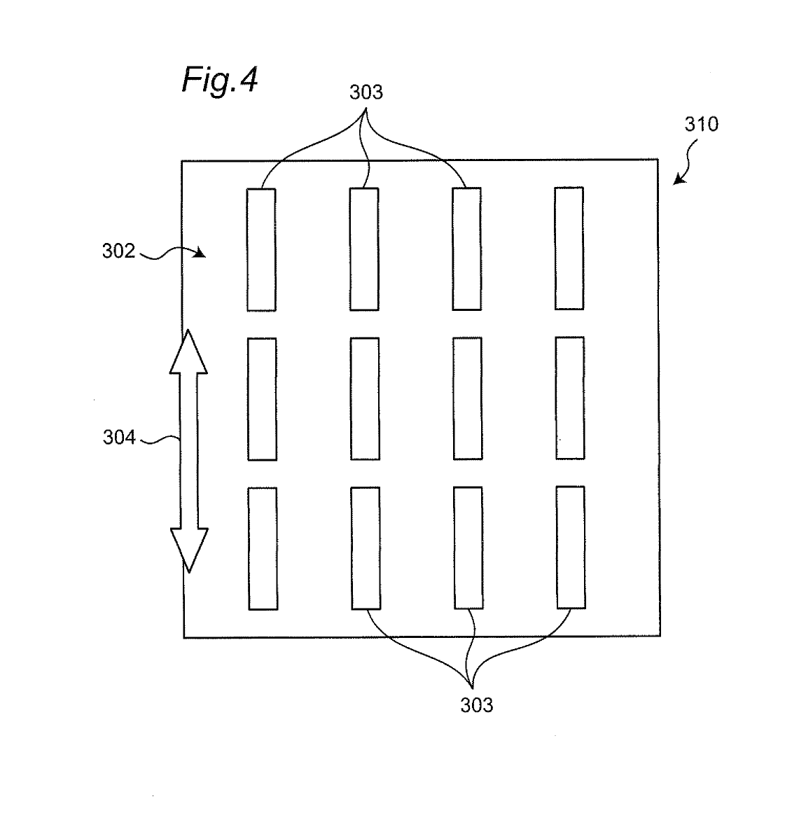

As a comparative example, an electromagnetic wave shielding member 310 having a conductor plate 303 in vertically long rectangular strip shape will be described with reference to FIG. 4. In the electromagnetic wave shielding member 310, first conductor plates 303 and second conductor plates (not shown) in the same strip shape are arranged opposed to each other on both surfaces of a transparent dielectric layer 302. In addition, the first conductor plates 303 and the second conductor plates are arranged independent from each other at regular intervals in planes of the dielectric layer 302. In FIG. 4, as the structure in which the first conductor plates 303 are arranged independent from each other at regular intervals, all the first conductor plates 303 have the same shape (by way of example, the vertically long rectangular shape) and the same size, and are arranged on one surface of the dielectric layer 302 at equal intervals in a 3×4 matrix form of 3 longitudinal rows and 4 lateral columns. Each of the second conductor plates, not shown, has the same shape and the same size as each of the first conductor plates 303, and is arranged in the same position as the first conductor plate 303 in the same manner.

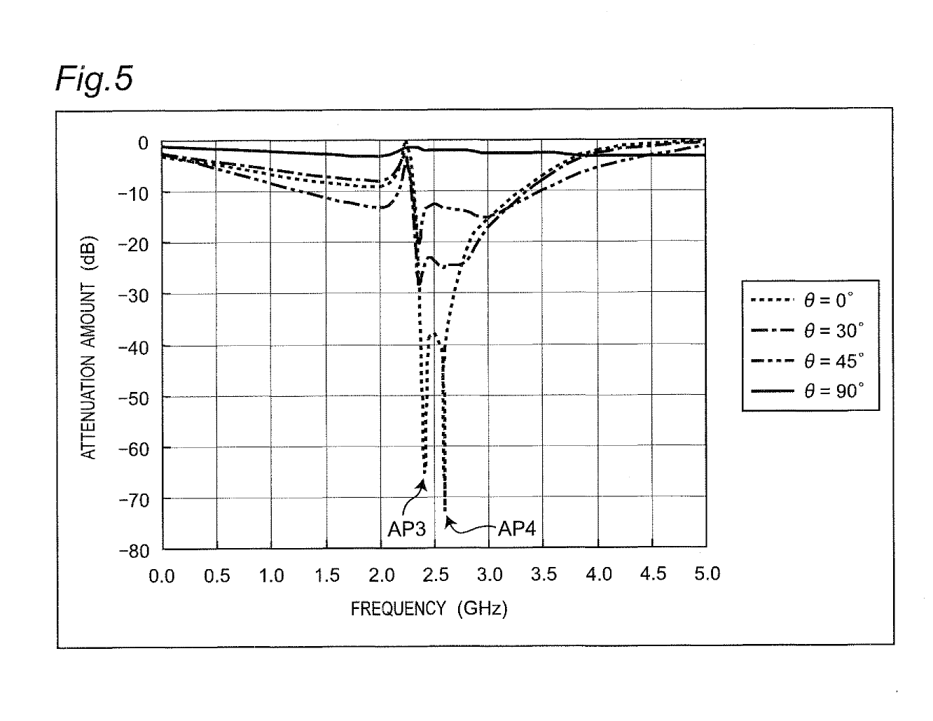

A more specific example is as follows. Each of the first conductor plates 303 and each of the second conductor plates in strip shape have a length of 25 mm in a long side direction, and a length of 5 mm in a short side direction. A distance between the adjacent first conductor plates 303 (the adjacent second conductor plates) in the short side direction is 21 mm. A distance between the adjacent first conductor plates 303 (the adjacent second conductor plates) in the long side direction is 1 mm. In addition, as in FIGS. 1 and 2, the dielectric layer 302 is a glass having a relative permittivity of 7, and has a thickness of 2.5 mm. A direction of a polarized wave of an electromagnetic wave is a direction 304 in FIG. 4. FIG. 5 shows pass-through characteristics of the electromagnetic wave shielding member 310. As in each of the first conductor plates 101 and each of the second conductor plates 102 in square frame shape of the first embodiment, an attenuation pole AP3 at 2.4 GHz and an attenuation pole AP4 at 2.6 GHz are generated in the polarized wave at angle θ=0 with respect to the direction 304. However, each of the pass-through characteristics is changed according to the polarized wave. When angle θ is close to 90°, steepness of each of the attenuation poles is reduced to make an attenuation amount smaller. This can be accepted when the electromagnetic wave shielding member 310 is used in an environment in which the polarized wave is fixed. However, the electromagnetic wave is reflected on a furnace wall of a microwave heating furnace or a casing of a microwave oven. In addition, the direction of the polarized wave is unpredictable from the effect of a shape of a material to be heated. Therefore, the electromagnetic wave shielding member 310 of the comparative example may not be able to shield the electromagnetic wave according to the direction of the polarized wave of the electromagnetic wave.

On the contrary, the electromagnetic wave shielding member 10 according to the first embodiment is required to shield the electromagnetic wave regardless of the direction of the polarized wave of the electromagnetic wave. For this purpose, arrangements of the conductor plates 101 and 102 will be focused and described below.

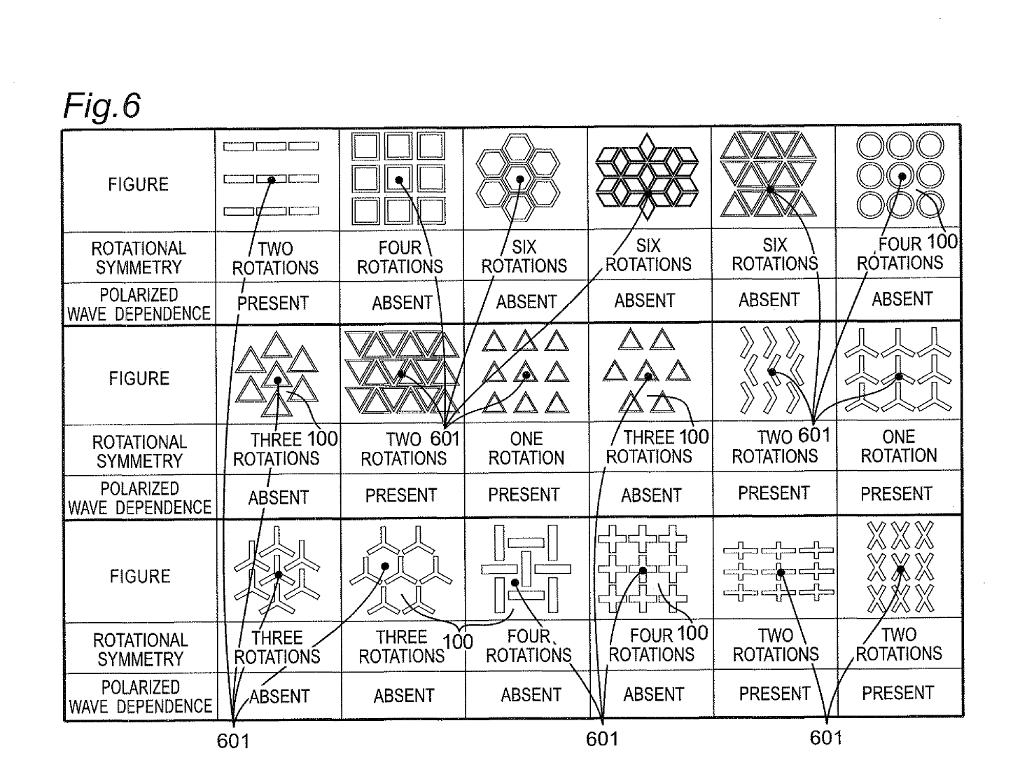

FIG. 6 shows various shapes of the first conductor plates 101 and the second conductor plates 102 and the presence or absence of polarized wave dependency. In addition, the arrangements of the conductor plates 101 and 102 have rotational symmetry about a rotational symmetry center 601. In FIG. 6, about an optional reference point in each of the planes of the dielectric layer 201 on which the first conductor plates 101 are arranged, the polarized wave dependency is found when the first conductor plates 101 have one-fold rotational symmetry (rotational symmetry each time the first conductor plates 101 are rotated 360°=360°/one rotation) or two-fold rotational symmetry (rotational symmetry each time the first conductor plates 101 are rotated 180°=360°/two rotations). On the contrary, about the optional reference point, the polarized wave dependency is not found when the first conductor plates 101 have three or more-fold rotational symmetry (rotational symmetry each time the first conductor plates 101 are rotated 120°=360°/three rotations or rotated to an angle less than 120 (360°/n rotations) [where n is an integer of 4 or more]). That is, in each of the arrangements of the conductor plates 101 and 102, three or more-fold rotational symmetry is required to shield the electromagnetic wave regardless of the direction of the polarized wave of the electromagnetic wave. The optional reference point is not required to be located on the first conductor plate 101 or the second conductor plate 102. In addition, the rotational symmetry center 601 is an example of the optional reference point, and does not represent all rotational symmetry centers.

In FIG. 6, the following specific structures can be used as the first embodiment and a modification example thereof without the polarized wave dependency. The second to sixth conductor plates from the left in the top column are all formed in frame shape (quadrangular frame, hexagonal frame, parallelogrammatic frame, triangular frame, and circular frame). The first and fourth conductor plates from the left in the second row are all formed in triangular frame shape. The first to fourth conductor plates from the left in the bottom row are all formed in Y-shape, rectangular shape, and cross shape in planar plate shape. When the conductor plates have planar shape, an aperture is provided by each of the gaps 100 between the conductor plates to ensure visibility.

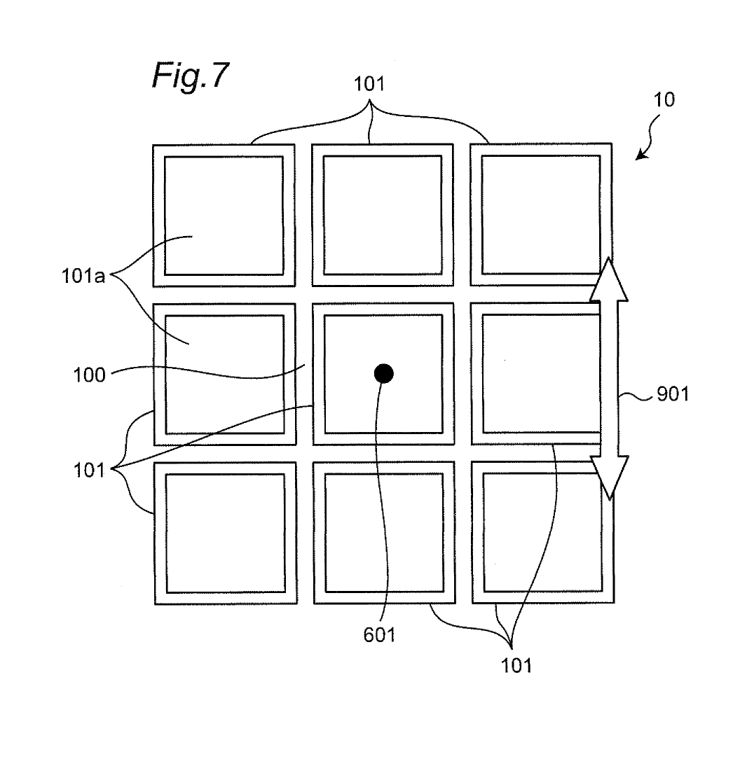

Referring to FIG. 7, there will be described a principle in which the conductor plates having three or more-fold rotational symmetry shield the electromagnetic wave regardless of the direction of the polarized wave. In FIG. 7, the first conductor plates 101 have four-fold rotational symmetry (rotational symmetry each time the first conductor plates 101 are rotated 90°=360°/four rotations). In addition, the figures are overlapped each time the first conductor plates 101 are rotated 90° about the rotational symmetry center 601. In FIG. 7, the electromagnetic wave having the polarized wave in the direction same as the direction 901 is incident onto the electromagnetic wave shielding member 10. At the time, in response to an electric field of the electromagnetic wave, the electric current mainly flows into a component in the direction same as the direction 901 of each of the first conductor plates 101. Thus, the first conductor plate 101 is electromagnetically coupled to the adjacent first conductor plate 101 on the dielectric layer 201 and the opposing second conductor plate 102 across the dielectric layer 201 to form the attenuation poles. In addition, when the electromagnetic wave having the polarized wave in a direction orthogonal to the direction 901 is incident onto the electromagnetic wave shielding member 10, in response to the electric field of the electromagnetic wave, the electric current mainly flows into a component in the direction orthogonal to the direction 901 of each of the first conductor plates 101. Thus, the first conductor plate 101 is electromagnetically coupled to the adjacent first conductor plate 101 on the dielectric layer 201 and the opposing second conductor plate 102 across the dielectric layer 201 to form the attenuation poles. The arrangement of the first conductor plate 101, the adjacent first conductor plate 101 seen from the component in the direction same as the direction 901 of the first conductor plate 101, and the opposing second conductor plate 102 on a back surface of the dielectric layer 201 is exactly the same as the arrangement of the first conductor plate 101, the adjacent first conductor plate 101 seen from the component in the direction orthogonal to the direction 901 of the first conductor plate 101, and the opposing second conductor plate 102 on the back surface of the dielectric layer 201. When the first conductor plates 101 are rotated 90° about the rotational symmetry center 601, the electric current flows in exactly the same manner. Accordingly, the attenuation poles are generated at the same frequency, and the pass-through characteristics coincide with each other.

When the electromagnetic wave having the polarized wave in a direction in which angle θ with respect to the direction 901 is 0°<θ<90° is incident, the incident electromagnetic wave is divided into the component in the direction same as the direction 901 and the component in the direction orthogonal to the direction 901. In response to the electric field of the electromagnetic wave, the electric current flows into the component in the direction same as the direction 901 of each of the first conductor plates 101 and the component in the direction orthogonal to the direction 901. The first conductor plate 101 is electromagnetically coupled to the adjacent first conductor plate 101 and the opposing second conductor plate 102 to form the attenuation poles. As in FIG. 7, the arrangement of the first conductor plate 101, the adjacent first conductor plate 101 seen from the component in the direction same as the direction 901 of the first conductor plate 101, and the opposing second conductor plate 102 on the back surface of the dielectric layer 201 is exactly the same as the arrangement of the first conductor plate 101, the adjacent first conductor plate 101 seen from the component in the direction orthogonal to the direction 901 of the first conductor plate 101, and the opposing second conductor plate 102 on the back surface of the dielectric layer 201. When the first conductor plates 101 are rotated 90°, the electric current flows in exactly the same manner. Accordingly, the attenuation poles are generated at the same frequency, and the pass-through characteristics coincide with each other. That is, all the pass-through characteristics with respect to the electromagnetic wave having the polarized wave in the direction same as the direction 901, in the direction orthogonal to the direction 901, and in the direction in which angle θ with respect to the direction 901 is 0°<θ<90° coincide with each other.

These features are common in the electromagnetic wave shielding member 10 including the dielectric layer 201, the first conductor plates 101 arranged on one surface of the dielectric layer 201, the second conductor plates 102 arranged opposed to the first conductor plates 101 on the other surface of the dielectric layer 201, the second conductor plates 102 having the same shape as the first conductor plates 101, wherein the first conductor plates 101 and the second conductor plates 102 are arranged at regular intervals to have three or more-fold rotational symmetry about the optional reference point 601 on the one surface of the dielectric layer 201 on which the first conductor plates 101 are arranged, and are arranged independent from each other to form each of the gaps 100 between the adjacent conductor members. The electromagnetic wave shielding member 10 of the first embodiment of the present invention can shield the electromagnetic wave regardless of the direction of the polarized wave of the electromagnetic wave.

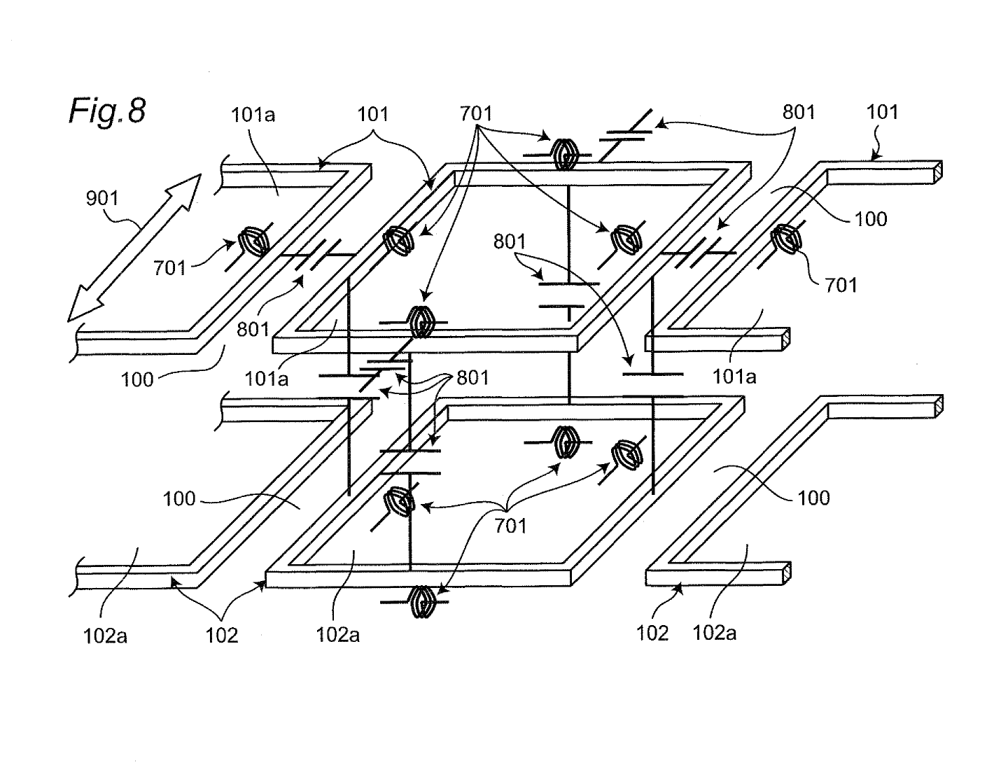

Referring to FIG. 8, a size of each of the first conductor plates 101 and each of the second conductor plates 102 will be described. In FIG. 8, illustration of the dielectric layer 201 is omitted. The frequency of the attenuation poles is expressed by Equation (2). A capacitance component C and an inductance component L in Equation (2) are determined according to the size of the first conductor plate 101 and the second conductor plate 102. From a relation between the size of the conductor plates, and C and L, a dimension of the first conductor plate 101 or the second conductor plate 102 in the direction same as the direction 901 and a dimension of the first conductor plate 101 or the second conductor plate 102 in the direction orthogonal to the direction 901 are approximately half a wavelength of the frequency of the attenuation pole. However, as in the electromagnetic wave shielding member 10 of the first embodiment of the present invention, when there exist the adjacent first conductor plate 101 on the periphery and the opposing second conductor plate 102, as shown in FIG. 8, the frequency is shifted from the frequency calculated by Equation (2) to the low frequency side due to influences of inductances 701 or capacitances 801 parasitized between the first conductor plate 101 and the peripheral conductor plate. The dimension of the first conductor plate 101 or the second conductor plate 102 in the direction same as the direction 901 and the dimension of the first conductor plate 101 or the second conductor plate 102 in the direction orthogonal to the direction 901 are thus made smaller than half the wavelength of the frequency of the attenuation pole. The frequency of the attenuation pole is thus shifted to the high frequency side to be set to the desired frequency.

$$f = \frac{1}{2 π \sqrt{LC}} \qquad ( 2 )$$

where f: resonance frequency, L: inductance, and C: capacitance.

Here, a wavelength of the electromagnetic wave will be described. The wavelength of the electromagnetic wave is expressed by light velocity/frequency in a vacuum; for example, at 2.45 GHz, 300,000 km/2.45 GHz=approximately 120 mm. However, a wavelength in a line formed on the dielectric layer is shortened by an effective dielectric constant determined from its relative permittivity. This phenomenon is referred to as a wavelength shortening effect, and is expressed as in Equation (3).

$${λ}_{g} = \frac{λ}{{ɛ}_{rel}} \qquad ( 3 )$$

where λg: wavelength shortened by the dielectric layer, λ: wavelength in a vacuum, and ∈ᵣₑₗ: effective dielectric constant.

A length of half the wavelength of 2.45 GHz in a vacuum is approximately 60 mm. However, in the structure in FIGS. 1 and 2, due to the influences of adjacent and opposing conductor plates and the wavelength shortening effect, both the dimension in the direction same as the direction 901 and the dimension in the direction orthogonal to the direction 901 are 15 mm. In addition, as in the structure in FIG. 4, due to the influences of the adjacent and opposing conductor plates and the wavelength shortening effect, the dimension in the direction same as the direction 901 is 25 mm. The structure in FIG. 4 does not respond to the polarized wave in the direction orthogonal to the direction 901. As a result, the dimension in the direction orthogonal to the direction 901 will not be half the wavelength.

Next, a method for designing the electromagnetic wave shielding member 10 according to the first embodiment of the present invention will be described.

Generally, to check whether the electromagnetic wave shielding member 10 having such a conductor pattern satisfies requirement performance, an electromagnetic field simulator by a finite element method, a moment method, or an FDTD method is used.

At first, the shape of the first conductor plates 101 and the second conductor plates 102 having three or more-fold rotational symmetry is determined. Then, from Equation (3), in consideration of the wavelength shortening effect based on the relative permittivity of the dielectric layer 201, the dimension in the direction same as the direction 901 and the dimension in the direction orthogonal to the direction 901 are determined to be approximately half the wavelength.

The determined model is analyzed by the electromagnetic field simulator. When the frequency of the attenuation pole is too high, each of the first conductor plates 101 and each of the second conductor plates 102 are made larger. When the frequency of the attenuation pole is too low, each of the first conductor plates 101 and each of the second conductor plates 102 are made smaller. Such adjustment allows the attenuation poles to be generated at the desired frequency.

As described above, according to the electromagnetic wave shielding member 10 of the first embodiment of the present invention, a plurality of first conductor plates 101 and a plurality of second conductor plates 102 are arranged at regular intervals to have three or more-fold rotational symmetry about the optional reference point 601 on one surface of the first dielectric layer 201 on which the first conductor plates 101 are arranged, and are arranged independent from each other (to form each of the gaps 100). Therefore, the electromagnetic wave can be shielded regardless of the direction of the polarized wave of the electromagnetic wave. In addition, each of the first conductor plates 101 and each of the second conductor plates 102 can have the quadrilateral frame shape with the quadrilateral through-hole, the donut shape with the circular through-hole, or the cross punched shape. The through-holes 101a and 102a and each of the gaps 100 ensure an aperture ratio of e.g., 90% or more, which is higher than the aperture ratio of approximately 50% of the conventional art. Change in a state of a material to be heated can thus be easily checked visually. Further, a plurality of first conductor plates 101 or a plurality of second conductor plates 102 are not required to be connected to each other, and are arranged independent from each other on the first dielectric layer 201 (to form each of the gaps 100 between the adjacent conductor plates). Therefore, no members for connecting the conductor plates are necessary, and an area of each of the conductor plates can be reduced more greatly than in the conventional art.

According to the first embodiment, the plurality of first conductor plates 101 and the plurality of second conductor plates 102 are arranged at regular intervals to have three or more-fold rotational symmetry about the optional reference point 601 on the one surface of the first dielectric layer 201 on which the first conductor plates 101 are arranged, and are arranged independent from each other to form each of the gaps 100 between the adjacent conductor plates. In addition, each of the first conductor plates 101 and each of the second conductor plates 102 are arranged on the first dielectric layer 201 so that the through-holes 101a and 102a and each of the gaps 100 can ensure the aperture ratio higher than that in the conventional art. The aperture can thus be larger than that in the conventional art, so that the aperture ratio can be higher than that in the conventional art. Visibility of a material to be heated can thus be significantly improved.

### Modification Example

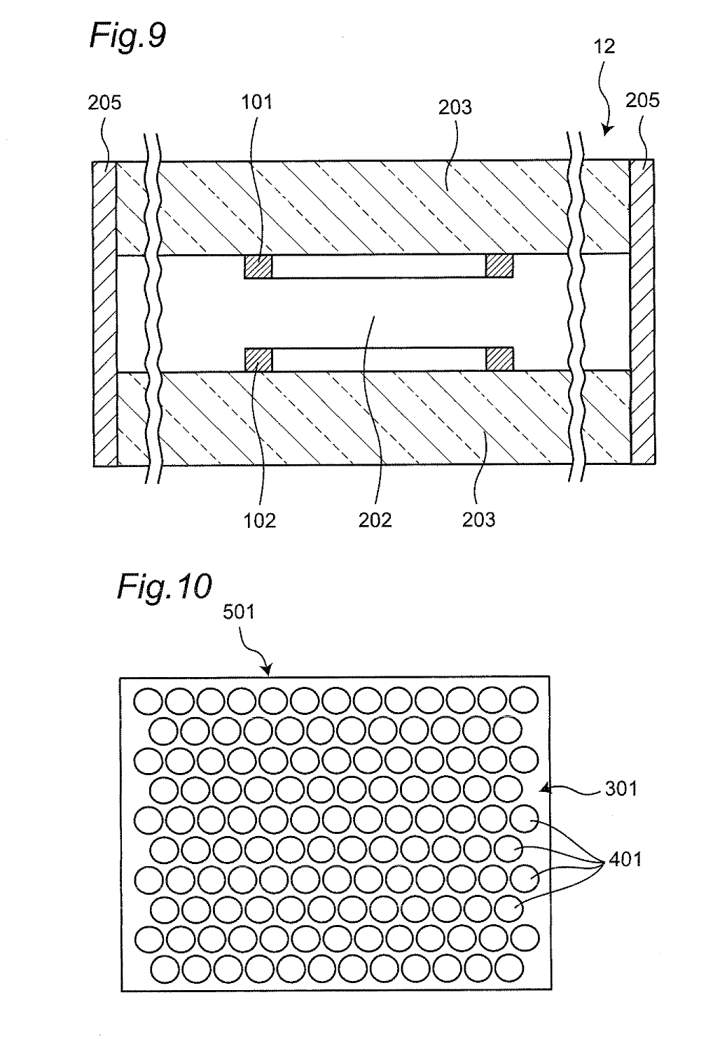

As a modification example of the first embodiment, an electromagnetic wave shielding member 12 which can reduce, not only an electromagnetic wave, but also heat conduction, will be described with reference to FIG. 9. The electromagnetic wave shielding member 12 includes a dielectric layer space 202 in which the dielectric layer 202 is gas or vacuum. The dielectric layer 202 is sandwiched between two second dielectric layers 203 to seal its space. In addition, each of the first conductor plates 101 and each of the second conductor plates 102 are arranged on opposing surfaces of the two second dielectric layers 203. More specifically, the two second dielectric layers 203 and sealing members 205 sealing the entire periphery of the two second dielectric layers 203 seal the dielectric layer space 202, and the dielectric layer space 202 is a space filled with gas or a space maintaining vacuum therein. In this case, using a relative permittivity of the gas or vacuum, the shape and dimension of the conductor plates 101 and 102 can be designed. Its operation principle and polarized wave dependency have been described above.

In addition, the dielectric layer space 202 between the two second dielectric layers 203 is sealed with gas having a low heat conductivity, or maintains the vacuum. The heat conduction can thus be reduced. Heat in the microwave heating furnace or the microwave oven cannot be transmitted to the outside, and heating can thus be efficiently performed. In addition, even when the user puts the face close to the window to check the interior thereof, the window is not hot and safety is secured.

In the above embodiment, each of the first conductor plates 101 and each of the second conductor plates 102 have the same shape and the same size. However, the present invention is not limited thereto, and can have different shapes and different sizes. However, for example, to simplify the design and manufacture, the conductor plates may have the same shape and the same size.

By properly combining arbitrary embodiments of the aforementioned various embodiments, the effects owned by each of them can be made effectual.

The electromagnetic wave shielding member of the present invention is capable of shielding the electromagnetic wave while ensuring the visibility, and has the frequency selectivity. Thus, the electromagnetic wave shielding member of the present invention is applicable to the window of the microwave heating furnace, the window of the microwave oven, wireless LAN security, and thermal insulation by shielding an infrared ray.

Although the present invention has been fully described in connection with the embodiments thereof with reference to the accompanying drawings, it is to be noted that various changes and modifications are apparent to those skilled in the art. Such changes and modifications are to be understood as included within the scope of the present invention as defined by the appended claims unless they depart therefrom.

What is claimed is:

1. An electromagnetic wave shielding member comprising:
a first dielectric layer;
a plurality of first conductor members arranged on one surface of the first dielectric layer; and
a plurality of second conductor members arranged opposed to the first conductor members on an other surface of the first dielectric layer,
wherein the first and second conductor members are arranged at regular intervals to have three or more-fold rotational symmetry about an optional reference point on the one surface of the first dielectric layer on which the first conductor members are arranged, and are arranged independent from each other to form a gap between adjacent conductor members.

2. The electromagnetic wave shielding member according to claim 1, wherein each of the first conductor members and each of the second conductor members have a same shape and a same size, and are arranged in a same position on the one surface and the other surface of the first dielectric layer.

3. The electromagnetic wave shielding member according to claim 1, wherein the first dielectric layer is constructed by a space surrounded by second dielectric layers and sealing members and filled with gas.

4. The electromagnetic wave shielding member according to claim 2, wherein the first dielectric layer is constructed by a space surrounded by second dielectric layers and sealing members and filled with gas.

5. The electromagnetic wave shielding member according to claim 1, wherein the first dielectric layer is constructed by a space surrounded by second dielectric layers and sealing members and maintaining a vacuum therein.

6. The electromagnetic wave shielding member according to claim 2, wherein the first dielectric layer is constructed by a space surrounded by second dielectric layers and sealing members and maintaining a vacuum therein.
